(19) United States
(12) Patent Application Publication
(10) Pub. No.: US 2008/0006850 A1
(43) Pub. Date: Jan. 10, 2008

(54) System and method for forming through wafer vias using reverse pulse plating

(75) Inventors: Kimon Ribnicek, Santa Barbara, CA (US); Gregory A. Carlson, Santa Barbara, CA (US); Paulo Silveira da Motta, Santa Barbara, CA (US); Jian Zhao, Goleta, CA (US)

Correspondence Address: JACQUELIN K. SPONG, 2139 DOMINION WAY, FALLS CHURCH, VA, 22043, US

(73) Assignee: Innovative Micro Technology, Goleta, CA (US)

(21) Appl. No.: 11/482,944

(22) Filed: Jul. 10, 2006

(51) Int. Cl. H01L 29/76; H01L 21/20

(52) U.S. Cl. 257/213; 438/584; 257/E21.597; 257/E21.584

(57) ABSTRACT

A method for forming through wafer vias in a substrate uses a Cr/Au seed layer to plate the bottom of a blind trench formed in the front side of a substrate. Thereafter, a reverse plating process uses a forward current to plate the bottom and sides of the blind hole, and a reverse current to de-plate material in or near the top. Using the reverse pulse plating technique, the plating proceeds generally from the bottom of the blind hole to the top. To form the through wafer via, the back side of the substrate is ground or etched away to remove material up to and including the dead-end wall of the blind hole.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to integrated circuit and microelectromechanical systems (MEMS) manufacturing. More particularly, this invention relates to a process for forming through wafer vias in an integrated circuit or MEMS substrate.

Microelectromechanical systems (MEMS) are integrated micro devices which may be fabricated using integrated circuit batch processing techniques. MEMS devices have a variety of applications including sensing, controlling and actuating on a micro scale. Accordingly, MEMS devices often include a moveable component acting as a sensor or actuator. Because the MEMS devices are generally moveable, they are also vulnerable to damage from handling or contamination. Therefore, the devices are often encapsulated with a lid wafer to protect the moveable component. In addition, some MEMS devices, such as infrared bolometers, require a vacuum environment to obtain optimum performance. Accordingly, a lid wafer may need to be sealed against the device wafer with a hermetic bond.

Electrical vias may allow electrical access to electronic devices or microelectromechanical systems (MEMS) which have been encapsulated with a lid wafer, to form a device package. In order to continually reduce the cost of such packages and circuits, the packing density of devices within the packages and circuits has been continually increased. In order to support the increase in packing density, the pitch between electrical vias for the devices has also continued to shrink. As a consequence, there is a desire to form vias of increasingly large aspect ratio, that is, the vias are tending to become increasingly long and narrow.

Long, narrow vias are often created by plating a conductive material into a hole formed in a substrate. FIG. 1 illustrates a typical prior art process for forming an electrical via by electroplating. A hole 14 is created in a substrate 12 by a directional material removal process such as reactive ion etching (RIE). A seed layer 16 is then deposited conformally over the etched surface, to provide a conductive layer to attract a plating species from the plating bath. Material is then plated into the hole 14 over the seed layer 16.

However, when using the approach illustrated schematically in FIG. 1, the plated material has a tendency to concentrate at the corners 18 of the blind hole 14. This tendency results from the proportionately larger density of field lines emanating from the corners, and from geometric considerations, that is, the aspect ratio of the via. Since the via is deeper than it is wide, the build up of material in the cylinder of the via will close off the cylinder before the plated material reaches the top of the substrate and completely fills the hole. Since the aperture of the via has become closed, the plating bath no longer circulates and the confined bath within the hole is exhausted of its plating species. Plating into the hole will then cease, and a void is formed beneath the point of closure of the via aperture. Since these problems worsen as the via becomes longer and narrower, the approach illustrated in FIG. 1 becomes increasingly difficult for long, narrow vias.

Specialized bath chemistries have been developed that reduce the negative effects cited above, but they can be expensive and difficult to control. Most often, special plating bath additives are employed that selectively suppress grain growth on the sides of the via hole. Alternatively, U.S. Pat. No. 6,399,479 describes a technique whereby a plating seed layer is deposited primarily on the base of the via rather than on its sidewalls, by high density plasma physical vapor deposition (HDP-PVD). Subsequent plating into the via then proceeds from the bottom of the via upwards. However, most PVD systems are greatly restricted in their ability to deposit metal down deep trenches, and the plating base thickness may drop dramatically with increasing depth, limiting the aspect ratio of the vias to which this technique may be applied. The HDP-PVD systems may also be hazardous to operate.

Another known method for making vias is to use an anisotropic wet etch to form the holes with sloping sidewalls, and to deposit the conductive material on the sloped walls of the holes. However, this method often results in the conductive material having non-uniform thickness, and the heat conduction in the thin deposited layer is relatively poor. Hermeticity is also difficult to achieve because the material does not fill the via, but merely coats the sidewalls of it. The aspect ratio must also remain near 1:2 (width=2× depth) to allow room for the sloping sidewalls resulting from the wet etching technique, thus limiting the density of the vias.

### SUMMARY

Systems and methods are described here which address the above-mentioned problems, and are particularly applicable to the formation of long, narrow vias by plating. The systems and methods use a particular composition of plating seed layer, a chromium and gold multilayer, which can be deposited uniformly down relatively deep, narrow holes. The systems and methods then use reverse pulse plating to plate the material onto the seed layer. The reverse pulse plating process reverses the polarity of the plating bath electrodes on an intermittent basis. The reverse polarity pulses tend to remove material in areas of high field line concentration, i.e. at the corners of the vias. By adjusting properly the relative duration of the forward pulse to the reverse pulse, the vias can be plated without restricting the aperture at the top of the via prematurely. Using the systems and method described here, relatively long, narrow vias can be made, with aspect ratios exceeding eight-to-one (depth to width), for example.

The systems and methods include forming at least one trench with a dead-end wall in a front side of a substrate, forming a seed layer in the trench, using reverse pulse plating to deposit a conductive material in the trench, and removing material from a back side of the substrate to a point at which the dead-end wall of the trench has been removed, thereby forming the through wafer via. The seed layer may comprise a layer of chromium and a layer of gold. The reverse pulse plating process may include a) applying a forward current for a first duration; b) applying a reverse current for a second duration; c) applying no current for a third duration; and d) repeating steps a) through c) for about 8 hours.

In one exemplary embodiment, a 100 μm deep blind hole is etched into a silicon wafer about 500 μm thick. A layer of chromium about 1000 Angstroms thick is then deposited into the blind hole followed by a layer of gold about 5000 Angstroms thick. The blind hole is then plated using reverse pulse plating, which plates material generally from the bottom of the via upward, by removing a portion of the material deposited near the sharpcornered features, before plating additional material over the whole surface.

Having formed the blind hole, the MEMS device may then be fabricated on the surface of the substrate. The MEMS device may be, for example, an electrostatic cantilevered beam. The MEMS device may then be encapsulated to protect it from damage, by adhering a lid wafer to the substrate supporting the MEMS device. After encapsulation, the through wafer vias may be formed by removing about 400 μm of material from the exposed back side of the substrate, up to a point beyond the dead end wall of the blind hole. This then forms a via through the thickness of the wafer or substrate.

In another exemplary embodiment, the blind hole is formed in the device layer of a silicon-on-insulator (SOI) substrate, through the thickness of the device layer and down to the buried oxide layer. After formation of the MEMS device over the blind holes, the handle layer of the SOI substrate may be removed and the vias etched through the buried oxide, forming the through wafer vias in the remaining device layer. Alternatively, the blind holes may be formed in the handle layer, and the device layer subsequently removed to form the through hole vias in the remaining handle layer.

The through wafer vias may then be used to provide an external electrical connection to the device sealed beneath the lid wafer. Electrical contacts may be used to probe the device to establish its functionality, before the individual devices are singulated from the wafer. Thus, the through wafer vias described here may reduce the cost of the finished devices, by allowing the vias to be placed closer together to reduce the amount of surface area consumed by the vias, and by allowing the device to be probed before performing additional process steps.

These and other features and advantages are described in, or are apparent from, the following detailed description.

### BRIEF DESCRIPTION OF THE DRAWINGS

Various exemplary details are described with reference to the following figures, wherein:

FIG. 1 is a cross sectional view showing a prior art approach to the formation of a plated via;

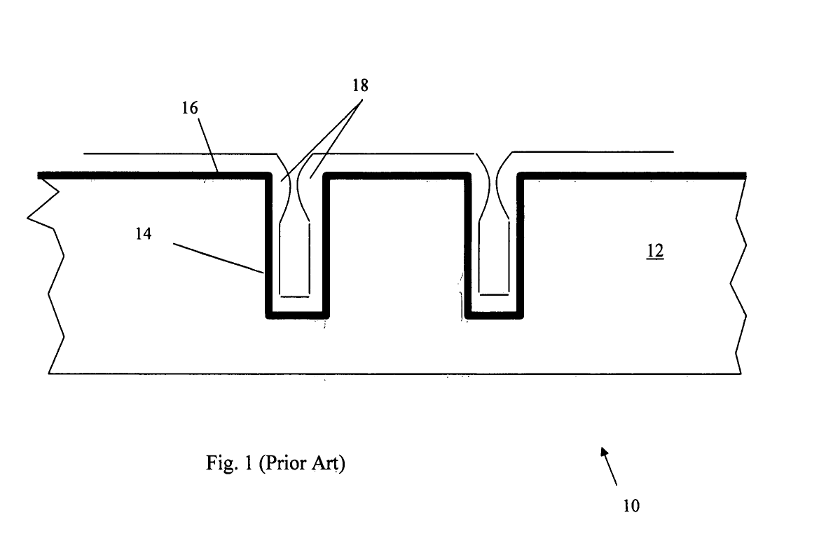

FIG. 2 is a cross sectional view of an exemplary substrate after formation of the blind trenches;

FIG. 3 is a cross sectional view of the exemplary substrate after a deposition of the seed layer;

FIG. 4 is a cross sectional view of the exemplary substrate during the reverse pulse plating process;

FIG. 5 is a diagram of an exemplary pulse train for use in the reverse pulse plating process;

FIG. 6 is a cross sectional view of the exemplary substrate after the reverse pulse plating process;

FIG. 7 is a cross sectional view of the exemplary substrate after completion of the through wafer vias;

FIG. 8 is a cross sectional view of an exemplary MEMS device using the through wafer vias; and

FIG. 9 is a flow diagram of an exemplary method for forming an encapsulated MEMS device with through wafer vias.

### DETAILED DESCRIPTION

The systems and methods described herein may be particularly applicable to microelectromechanical (MEMS) devices, wherein the vias may be required to carry a relatively large amount of current. MEMS devices are often fabricated on a composite silicon-on-insulator (SOI) wafer, consisting of a relatively thick (about 400-725 μm) “handle” layer of silicon overcoated with a thin (about 1-4 μm) layer of buried silicon dioxide, and covered with a silicon “device” layer about 5-100 μm thick. In the embodiment described below, the handle layer is about 500 μm thick, the oxide layer is about 2 μm thick, and the device layer is about 80 μm thick, and the through wafer vias may be formed in this device layer. However, it should be understood that this embodiment is exemplary only, and that the through wafer vias may be formed in simple a Si substrate, or in the device layer or handle layer of an SOI substrate, for example, before the formation of the MEMS device on top of the substrate and vias. The MEMS device may then be made, for example, by additive and subtractive thin-film processing. Movable features may be freed by, for example, wet or dry etching a selectively etchable, intermediate sacrificial layer from beneath the moveable feature. The moveable features may then be hermetically encapsulated in a cap or lid wafer, which is bonded or otherwise adhered to the top of the via/device wafer, to protect the moveable features from damage from handling and/or to seal a particular gas in the device as a preferred environment for operation of the MEMS device. After formation and encapsulation of the MEMS device, the back side of the via substrate may be ground to remove the dead end walls of the blind holes, and form the through wafer vias. Each of these processes is described in further detail below.

Through-hole vias are particularly convenient for encapsulated MEMS devices, because they may allow electrical access to the encapsulated devices. Without such through holes, electrical access to the MEMS device may have to be gained by electrical leads routed laterally under the lid wafer which is hermetically sealed over the MEMS device. It may be problematic, however, to achieve a hermetic seal over terrain that includes the electrical leads unless more complex and expensive processing steps are employed. This approach also makes radio-frequency applications of the device limited, as electromagnetic coupling will occur from the metallic bondline disposed over the laterally oriented leads. Alternatively, the electrical access may be achieved with vertically oriented through-wafer vias formed in a simple silicon substrate for example, or through the handle layer or device layer of an SOI wafer, using the systems and methods described here.

As mentioned above, the through hole vias may be constructed by first forming a blind trench in the substrate, and then forming a plating seed layer in the blind trench. It should be understood that although the word “trench” is used, the term should be construed as including any shape of opening, including a circular hole. A “blind trench” or “blind hole” may be an opening formed in one side of a substrate, which does not extend through the whole thickness of the substrate, such that the trench ends with a dead end wall in the substrate material. A “through hole” or “through wafer via” should be construed to mean an electrical conduit which extends completely through a material, for example, through a layer, wafer or substrate.

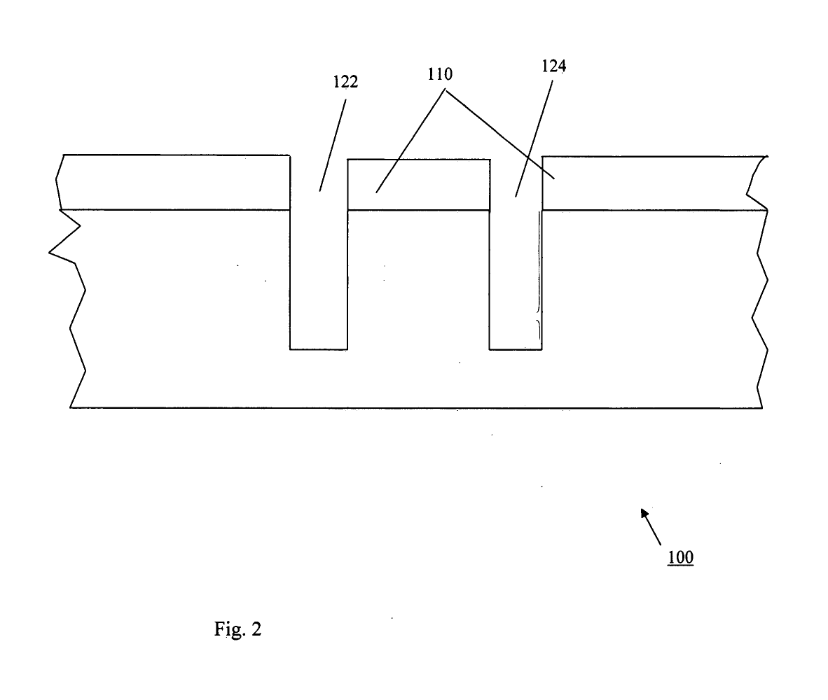

FIG. 2 is a cross sectional view of an exemplary substrate 100 after formation of the blind trenches. The substrate 100 may be, for example, a moderately resistive substrate such as silicon, float zone silicon or any of a number of other common substrate materials, such as ceramic or glass. As mentioned above, the blind trenches can also be created in the 80μm thick device layer of an SOI wafer, extending to a dead end wall formed by the buried oxide layer. The substrate 100 is first coated with photoresist 110 and exposed in regions where the blind trenches, or blind holes 122 and 124 are to be formed. The photoresist 110 is exposed and developed, such that areas which have been exposed are dissolved and removed, if using a positive photoresist. If using a negative photoresist, the areas which have not been exposed may be dissolved and removed. The means for forming the blind trenches or holes 122 and 124 may be, for example, deep reactive ion etching (DRIE), which is performed on the region of the substrate over which the photoresist has been dissolved and removed. In the case of an SOI wafer, the buried oxide may form a convenient etch stop for the DRIE process. The blind trenches may be between, for example, about 20 μm and about 50 μm wide and about 80 μm to about 150 μm deep. However, it should be understood that these dimensions are exemplary only, and that the techniques described here may be used to form a via with an aspect ratio (depth to width) of at least about three to one, up to about 8 to 1. The remaining photoresist 110 may then be removed from the substrate 100. At this point, an electrically insulating layer may be formed over the substrate to further electrically isolate the vias from each other. For example, if the substrate 100 is conductive, such as a metal or doped silicon, a dielectric insulating layer such as a thermal oxide may be grown or deposited over the conductive substrate 100 and the blind trenches 122 and 124, to isolate each blind trench from the others.

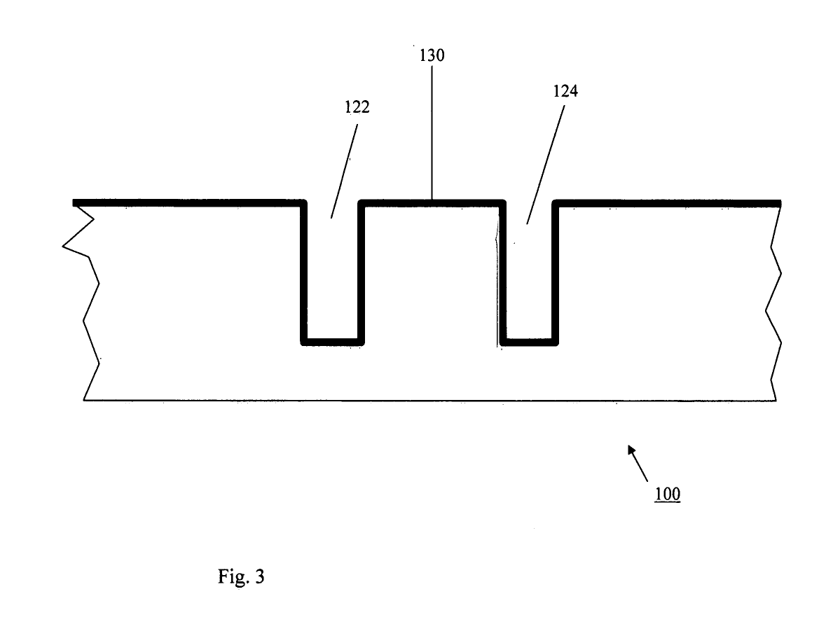

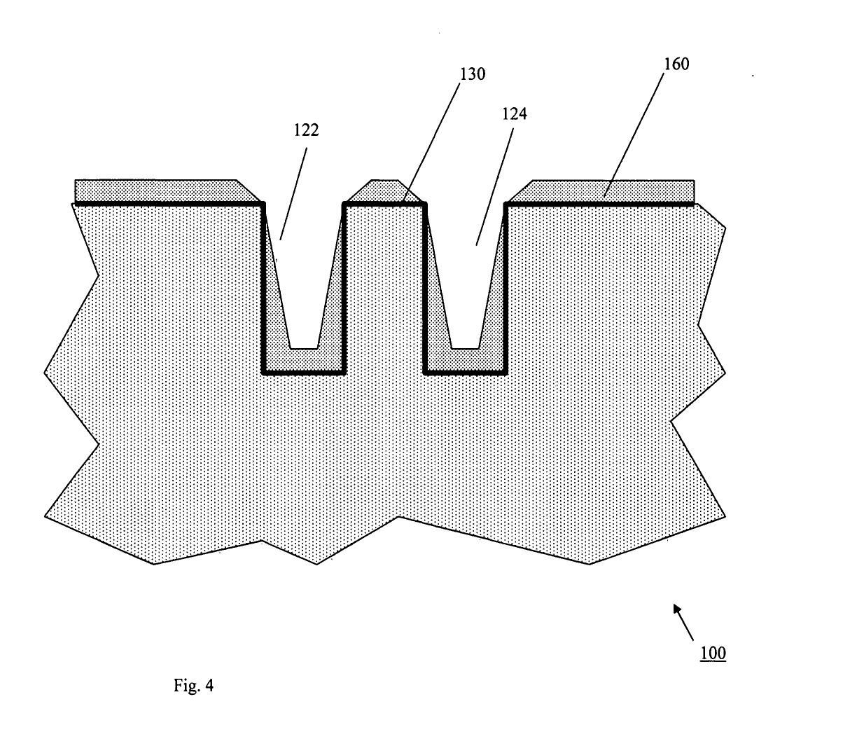

FIG. 3 is a cross sectional view of the exemplary wafer 100 after deposition of a seed layer structure. In FIG. 3, the seed layer structure 130 may be conformally deposited in the blind trenches 122 and 124. The seed layer structure 130 may be a two part system, for example, a layer of chrome (Cr) as an adhesion layer and a layer of gold (Au) as a conductive plating base layer, which are deposited on the substrate 100 and in the blind trenches 122 and 124. While a Cr/Au seed layer structure is described here, it should be understood that the adhesion layer may be composed of any of a number of other materials, which are effective for adhesion of the plating base layer into the blind hole, including titanium (Ti), titanium tungsten (TiW), copper (Cu) and nickel (Ni). The Cr/Au seed layer structure 130 may be deposited by, for example, chemical vapor deposition (CVD), ion beam deposition, e-beam deposition, evaporation or sputtering. For example, the seed layer structure 130 deposition can be accomplished by a simple PVD sputter deposition system, such as the OnCore sputter deposition tool manufactured by Tegal Corporation of Petaluma, Calif., at relatively low temperatures, for example, less than 100 degrees centigrade. The initial adhesion layer of Cr, Ti or other material may be deposited at thicknesses of 50 Angstroms up to 1500 Angstroms, while the conductive plating base layer may be deposited at thicknesses of 3000 Angstroms up to one micron or more, so long as reasonably low resistance conductive path is made to the bottom of the vias. The conductive species 160 may then be electroplated onto the seed layer structure 130, as shown in FIG. 4.

Gold is chosen for the conductive plating base layer despite its relatively high cost, because it appears to have outstanding throwing power, or ability to be deposited into deeply recessed features. Gold appears to surpass the commonly used metals, such as copper (Cu), tungsten (W) or nickel (Ni) in this regard, as a plating base layer. In addition, because the deposition is performed at relatively low temperature, other previously deposited or defined features may exist on the wafer prior to the deposition of the gold plating base. Another advantage of using Au is that it does not reverse plate or etch during the Cu reverse pulse plating process which follows. Relatively high reverse plating currents can be applied, while maintaining the electrical integrity of the plating base.

FIG. 4 is a cross sectional view of the exemplary substrate 100 at the beginning of the deposition of the conductive species 160 into the blind trenches 122 and 124. The means for depositing the conductive material 160 may be a plating system, including a plating bath and a power supply. The deposition may be performed by immersing the substrate into the plating bath, and coupling the seed layer to one terminal of the power supply. The plating species dissolved in the plating solution then may then be deposited as a layer 160 over the seed layer 130. The plating of material 160 occurs preferentially on the bottom of the vias, as shown in FIG. 4, because of the technique used to plate the conductive species 160, described further below. The plating therefore proceeds generally from the lower portions of the vias upward, without forming the voids characteristic of the prior art techniques. Using the techniques described here, blind trenches may be plated with high aspect ratios of at least five-to-one and even in excess of eight-to-one.

The plating of the conductive species may be accomplished using reverse pulse plating. Generally, the method comprises plating the conductive species on all the conductive surfaces of the blind holes, and then de-plating a portion of the conductive species on the upper portions of the blind holes, near the top corners. The de-plating process generally requires performing the electroplating process with the electrical bias polarities reversed between the cathode and the anode terminals of the electroplating system. By adjusting the ratio of the charge driven between the terminals in the reverse direction relative to the charge driven between the terminals in the forward direction, the ratio of the amount of conductive species deposited on the upper sidewalls relative to the amount at the base of the blind hole, can be adjusted.

In various exemplary embodiments, the ratio of the forward charge to the reverse charge is about two to one, and more generally less than about ten to one. For example, a forward current of about 0.4 A may be applied to the terminals for about 100 msec, for a total forward charge of about 40 mCoulombs. A reverse current of about 4.0 A is then applied to the terminals, with the bias polarity reversed, for about 5 msec, for a total reverse charge of about −20 mCoulombs. More generally, the forward current may be between about 0.1 A to about 1 A, for about 10 msec to about 200 msec. A reverse current of about −1 A to about −10 A may then be applied to the terminals for between about 1 msec to about 10 msec. The design considerations involved in choosing the amount of forward charge relative to the amount of reverse charge may be the plating time required to plate up the entire via blind hole, balanced against the tendency of the via to close at the top before the via is fully plated, thereby forming a void. Using the recommended values set forth above, a plating time of about eight hours may be required. Decreasing the amount of forward charge relative to the amount of reverse charge, while assuring that the voids are not formed within the via, may increase the required plating time.

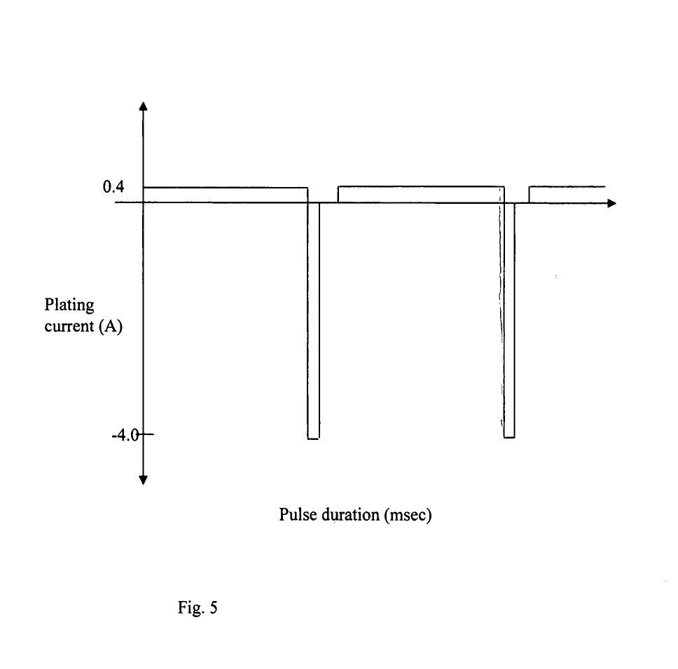

A pause between the reverse current pulse and the next positive current pulse may be used to allow the plating bath to circulate and the plating species concentrations to equilibrate. A pause of between about 1 msec and about 200 msec may be inserted between the reverse current pulse and the forward current pulse. More preferably, a pause of about 10 msec between each reverse current pulse and each following forward current pulse may be sufficient. A suitable exemplary pulse train for the combination forward and reverse pulse plating process is shown in FIG. 5.

Combination forward and reverse pulse plating processes, such as that depicted in FIG. 5, can be done with standard bath chemistries and have wide process windows. Using the reverse pulse plating techniques, no expensive additives are required in plating baths to plate high aspect ratio vias. The reverse pulse plating scheme can also be quickly adjusted on the fly to meet different plating requirements and topographies, using a homogenous plating bath chemistry.

The plated species may be copper (Cu), for example, plated by immersing the substrate 100 in a plating solution containing copper sulfate and sulfuric acid and performing the reverse pulse plating process. However, it should be understood that this embodiment is exemplary only, and that any other suitably conductive material which can be plated on the substrate, including gold (Au) or nickel (Ni), may be used in place of copper.

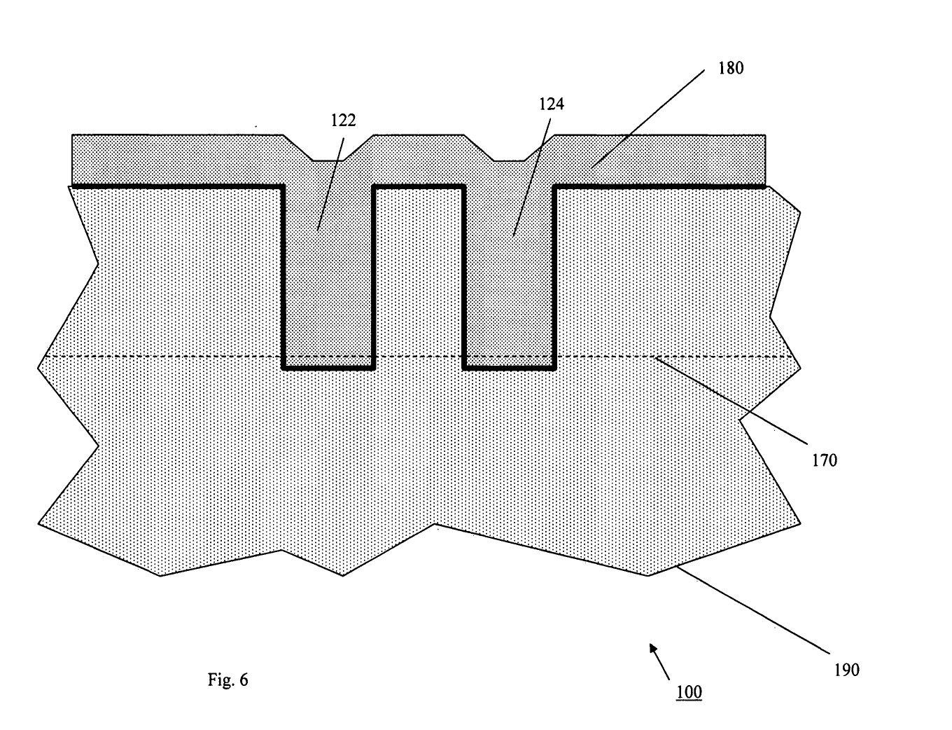

FIG. 6 is a cross sectional view of the exemplary substrate 100 after completion of the reverse pulse plating process. As shown in FIG. 6, the plating may proceed to a point at which the plating material 160 is deposited in and over the blind trenches 122 and 124. Therefore, the plating process may result in a non-planar top surface profile 180, which can be planarized using any known technique, such as chemical mechanical planarization (CMP). The CMP process may stop on the original substrate, such as Si, and therefore the CMP process may also remove the plating base seed layer 130. Otherwise, the seed layer 130 may need to be removed between the vias, by etching for example, before the contacts are formed, to assure that the contacts are not electrically connected by the conductive seed layer 130. The CMP may also stop on an oxide or other dielectric layer, if one was grown or deposited directly after the formation of the blind holes. The substrate 100, now called the “via substrate” may now be applied for use in conjunction with a MEMS device.

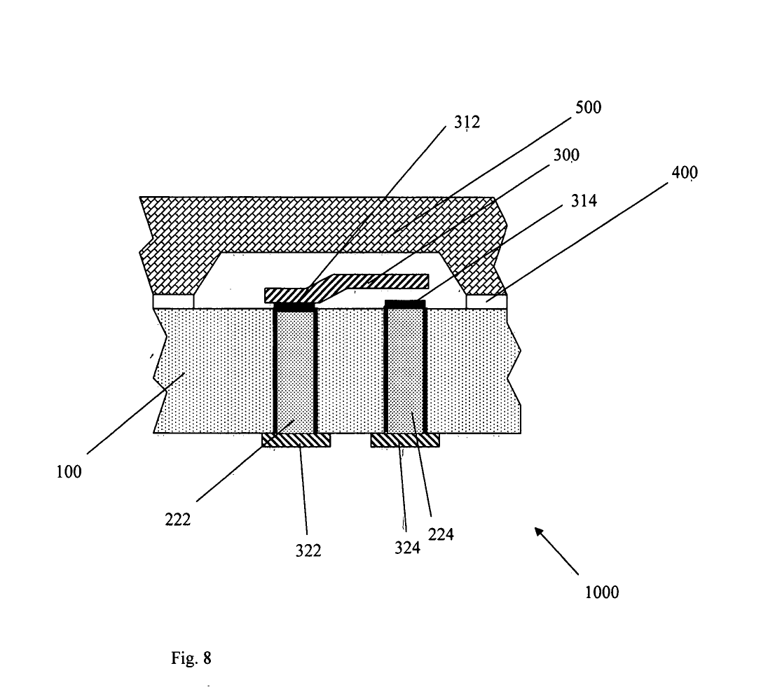

The via substrate 100 may, at this point, be bonded to another substrate, which has a previously fabricated MEMS device on its surface. The substrate may be either Si, or an SOI substrate, for example. The bonding mechanism may be, for example, eutectic, glass flit, polymer, or another other low-temperature bonding method, typically less than 300 degrees centigrade. The MEMS device may also be made first on top of the via substrate 100, then bonded to a lid wafer, also with a relatively low temperature process, such as eutectic bonding or glass frit bonding. Because there are metals on the via substrate, high temperature bonding may not be used. Additional details describing the formation of the MEMS device are set forth below, in reference to FIG. 8.

Finally, the through wafer vias may need to be formed from the blind trenches in the via substrate 100, by removing material from the exposed backside of the via substrate 100 up to the dead-end walls of the blind trenches. The through wafer vias may be formed by, for example, isotropic dry etching, single-sided wet etching or grinding, lapping, and polishing the back side 190 of the substrate 100, to remove material from the back side to a point 170 at which the dead end walls have been removed. In one embodiment, the means for removing material from the back side 190 of the substrate 100 may be a precision wafer grinder, such as a model VG-401 available from Okamoto of Japan. The grinder may use a metal wheel with diamond grit embedded in it as an abrasive. The rotation rate of the grinding wheel may be about 800 μm, and the rotation rate of the table holding the substrate 100 may be about 80 μm. Using these parameters, the grinding tool may be programmed to remove material at a rate of about 25 Mm per minute for about 15 minutes, to remove about 400 μm to about 450 μm of material, leaving the through wafer via substrate 100 having a thickness of about 50 μm to about 100 μm. At this point, the blind trenches 122 and 124 may become the through wafer vias 222 and 224.

Other techniques for removing material may be used, such as dry or single-sided wet etching, either alone or in combination with grinding, to remove about 400 μm of silicon from a 500 μm thick substrate, leaving about 100 μm of material as substrate 100. The etching can be done either before, but typically after the via substrate 100 is bonded to a device substrate. Accordingly, using the methods described here, through wafer vias of diameter less than about 50 μm and depths of at least about 100 μm may be made. More particularly, the aspect ratio of the via, that is, the ratio of the depth of the via to its width, may be at least one-to-one, and as great as about eight-to-one.

Alternatively, instead of removing material from the back side of the substrate, the through wafer vias 222 and 224 may be made using a silicon-on-insulator (SOD) composite substrate. The blind trenches may be etched as described above through a thick, 50 μm-100 μm device wafer, and coated with the seed layer structure and plated as before. However, using the silicon-on-insulator wafer, the handle wafer may be dry or wet etched, using the buried oxide as an etch stop. Vias may then be patterned in the now exposed, but previously buried oxide to ultimately allow a conductive path from subsequently defined metal pads and the through wafer vias. The buried oxide, being left on the majority of the substrate, also serves the purpose of electrical isolation between the top metallization layer and the substrate. In another alternative, the blind holes may be formed in the SOI handle layer, and the SOI device layer subsequently removed to form the through wafer vias.

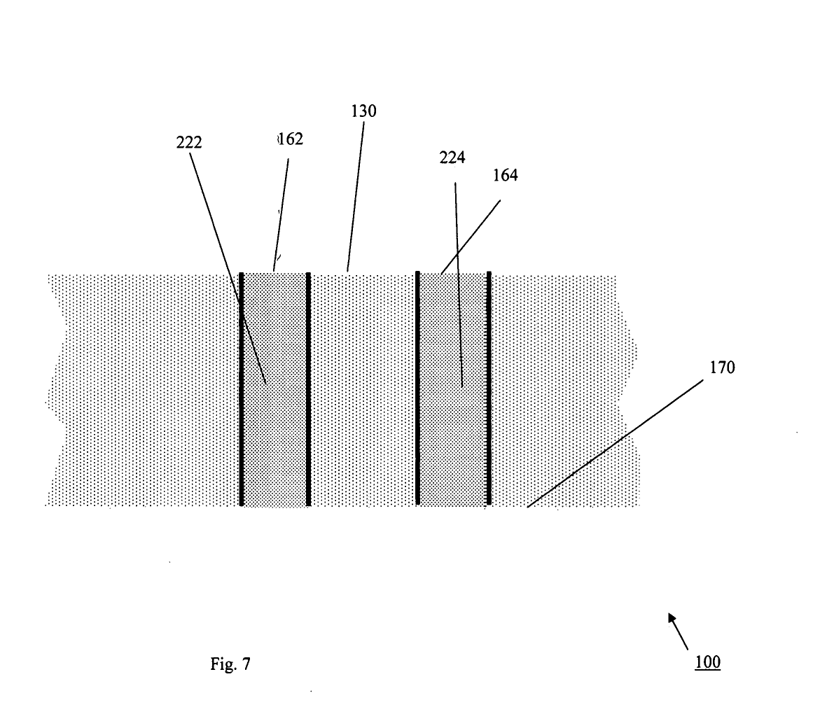

FIG. 7 shows via substrate 100 upon completion of the fabrication steps for the through wafer vias 222 and 224, after planarization of the top surface 180 and the grinding of the back side surface 190 to the point 170. The through wafer vias 222 and 224 may be completed by polishing the top surface 180 to a point at which the seed layer structure 130 has been removed from the top surface 180, and the bottom surface 170 has been background to remove material up to and including the blind walls. At this point, there may be no conductive path between the through wafer vias, as the plated material 162 within each through wafer via 222 and 224 may be electrically isolated from the plated material 164 within every other via 124 by the substrate material or insulating dielectric layer.

FIG. 8 shows an exemplary finished MEMS package 1000, sealed with a hermetic lid 500 and with the substrate 100 ground back to form the through wafer vias 222 and 224. The MEMS package 1000 may comprise an electrostatic switch or relay having a cantilevered device 300, which when the switch is activated, may touch a set of bottom contacts 314 to close a circuit. For example, a simple cantilevered device 300 may be fabricated on the via substrate 100 by first plating a sacrificial copper layer, then plating gold contacts over the sacrificial layer, and/or on the via substrate 100. A cantilevered nickel beam may then also be plated over the sacrificial copper layer. Finally, after removing the sacrificial copper layer, the nickel beam with gold contacts is free to bend about its anchor point. U.S. patent application Ser. No. 11/263,912 (Attorney Docket No. IMT-ThermalSwitch), incorporated by reference in its entirety, sets forth further details of the formation of a nickel cantilevered thermal MEMS switch which may be formed over a via substrate 100.

Alternatively, the MEMS device 300 may be made by forming moveable features in the device layer of another SOI wafer by, for example, deep reactive ion etching (DRIE) with the oxide layer forming a convenient etch stop. The movable feature is then freed by, for example, wet etching the oxide layer from beneath the moveable feature. The device layer may then be bonded face to face with a via substrate. The inner surface of the via substrate may be an integral part of the MEMS device, for example, switch contacts may be placed directly over the vias. Additional details as to the method of manufacture of such a cantilevered MEMS switch may be found in U.S. patent application Ser. No. 11/211,623 (Attorney Docket No. IMT-Wallis), U.S. patent application Ser. No. 11/211,624 (Attorney Docket No. IMT-Blind Trench) and U.S. patent application Ser. No. 11/359,558 (Attorney Docket No. IMT-SOI Release). Additionally, the through wafer via may be part of the lid wafer, carrying signals to the MEMS device through a connection in the bond line, while not actually being an active part of the device.

However, it should be understood that the MEMS device 300 may be any of a number of devices other than the switches described in the incorporated '912 application, '623 application, '558 application, or '624 application, such as accelerometers, sensors, actuators, and the like. Since the details of the MEMS device 300 are not necessary to the understanding of the systems and methods described here, it is depicted only schematically in FIG. 8. Similarly, the systems and methods disclosed here may also be applied to passive MEMS or non-MEMS devices, such as integrated circuits using the through wafer via substrate 100.

The through wafer vias 222 and 224 may be made using the reverse pulse plating process described above, to form a low-cost, highly conductive via with excellent thermal conductivity. However, the ability of the plated via to form a hermetic seal from one side of the wafer to the other may be limited by such factors as grain boundaries, and the propensity of the plated metal to crack and delaminate from the surrounding substrate, especially at elevated temperatures. A more hermetic seal may be made by providing thin pads 312 and 314 over the through wafer vias 222 and 224, as shown in FIG. 8. The pads 312 and 314 may be conductive, and may be formed from, for example, gold (Au).

The pads 312 and 314 may be formed before the MEMS device 300, by first depositing an adhesion layer such as chromium (Cr), followed by a layer of Au. A barrier layer, for example, molybdenum (Mo) may also be used to prevent the chromium of the adhesion layer from diffusing into the gold of the pad. The thickness of the pads 312 and 314 may be sufficient to provide a barrier to the transmission of gasses through the pad and therefore through the via, and therefore may increase the hermeticity of the encapsulated MEMS device 300. A thickness of between about 2500 Angstroms and about 1 μm of gold may be sufficient to provide this barrier. The Cr adhesion layer may be between about 50 Angstroms and about 1500 Angstroms thick, and the optional Mo layer may be about 100 Angstroms thick. Also, pads may be placed on the outer surface of the substrate, as probe pads 322 and 324, which in addition to providing a hermetic seal, allow the encapsulated device to be probed electrically from outside the encapsulation.

The gold pads 312 and 314 may be formed so that the edges extend slightly beyond the vias, about 5 μm beyond is typically sufficient to allow a misalignment tolerance and a good seal. The gold pad 312 and 314 can be formed using a lift-off process, or deposited, patterned and etched using dry or wet processes.

In addition to providing a barrier to the transmission of gasses, the pads 312 and 314 may also serve to keep the copper vias 222 and 224 from oxidizing during processing. Pad 314 may also be used as a switch contact as shown in FIG. 8. Although only a single pad 314 is shown in FIG. 8, it should be understood and another pad is located directly behind that shown, forming a pair of input and output contacts for the MEMS device 300.

After formation of the gold pads 312 and 314, and formation of the MEMS device 300, the MEMS cantilevered device 300 may be encapsulated in a cap or lid wafer 500, which has been relieved in areas to provide clearance for the movement of MEMS device 300. A hermetic seal may be made using any suitable adhesive 400, which may be applied to the bonding surfaces of the lid wafer 500. For example, the hermetic seal may be an alloy seal as taught in greater detail in U.S. patent application Ser. No. 11/211,625 (Attorney Docket No. IMT-Interconnect) and U.S. patent application Ser. No. 11/211,622 (Attorney Docket No. IMT-Preform) incorporated by reference herein in their entireties. The alloy seal may be an alloy of gold (Au) layers and indium (In) layer, in the stoichiometry of AuIn₂. Alternatively, the hermetic seal may be formed using a glass frit with embedded particles as a standoff, as taught in U.S. patent application Ser. No. 11/390,085 (Attorney Docket No. IMW-Standoff), incorporated by reference herein in its entirety.

Electrical contact to the encapsulated MEMS cantilevered device 1000 may be obtained with the through wafer vias 222 and 224. Contacts may be made by depositing a layer of a conductive material 322 and 324, onto the back side of substrate 100. The conductive material 322 and 324 may be, for example, gold pads about 0.5 μm or greater in thickness. As previously mentioned, these contacts 322 and 324 may serve as probe pads for testing the functionality of the encapsulated device 1000.

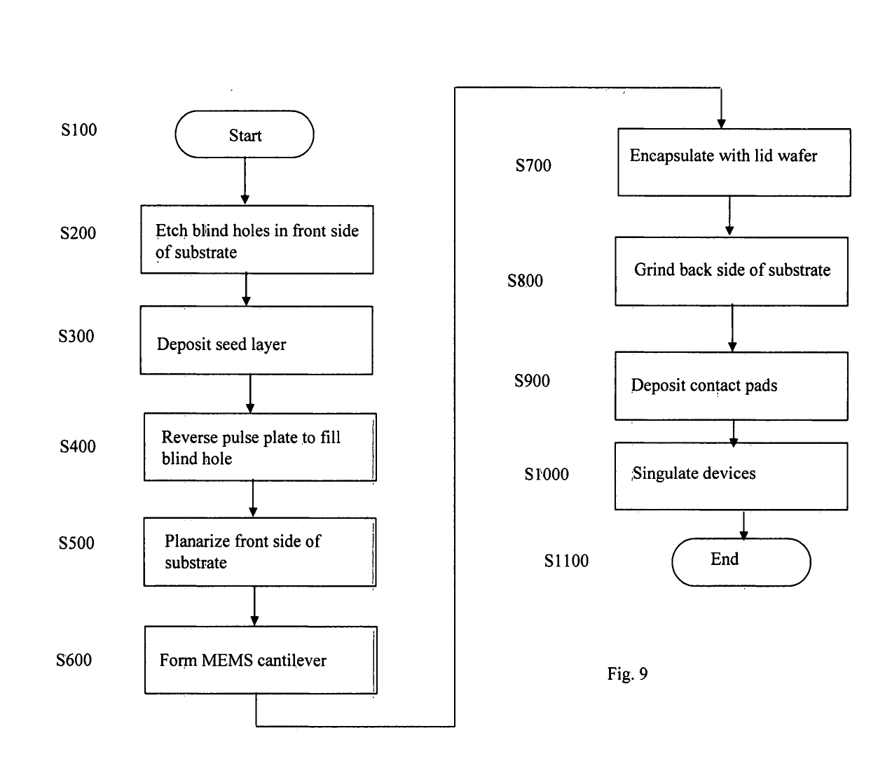

FIG. 9 is an exemplary flow chart describing a method for manufacturing a vacuum or inert gas encapsulated device with through wafer vias. The method begins in step S100 and proceeds to step S200, wherein blind trenches are etched in a substrate. The blind trenches may be formed by, for example, DRIE. The trenches may then be deposited with a layer of thermal oxidation, if electrical isolation is required from the substrate. In step S300, a seed layer structure may be conformally deposited over the blind trenches. In various exemplary embodiments, the seed layer structure may be a 1000 Angstrom thick Cr adhesion layer with a 5000 Angstrom thick Au plating base layer, deposited using physical vapor deposition. In step S400, the conductive material is deposited over the seed layer in the blind holes. In various exemplary embodiments, the conductive material may be deposited by reverse pulse plating. In step S500, the plated blind trenches are polished to planarize the surface of the substrate. The substrate may be planarized using, for example, chemical mechanical planarization. In step S600, the MEMS device may be fabricated on the front side of the through wafer via substrate. In various exemplary embodiments, the MEMS device may be a cantilevered electrostatic switch, for example. In step S700, the MEMS devices are encapsulated with a lid wafer hermetically sealed to the device wafer supporting the MEMS devices.

In step S800, material may be removed from the back side of the substrate to remove the dead end wall of the blind trench to form the through wafer vias. In various exemplary embodiments, the back side of the substrate may be ground or etched to remove the dead end wall of the blind trench.

The process may continue in step S900, wherein the contact probe pads may be deposited over the through wafer vias on the back side of the substrate. In step S1000, the devices may be singulated from the device wafer by, for example, saw cutting. The process ends in step S1100.

It should be understood that not all of the steps of the method illustrated in FIG. 9 may be required, and that the steps need not be performed in the order shown. For example, the contact probe pads may be deposited in step S900 before the MEMS device is fabricated in step S600, and the substrate may be ground in step S800 before formation of the MEMS device, in step S600. In addition, the devices need not be singulated in step S1000. It should also be understood that additional dielectric layers may be added to the sequence, for example, between the etching of the vias in step S200 and the deposition of the seed layer in step S300, and between the grinding of the substrate in step S800 and the deposition of the contact pads in step S900, to provide enhanced signal isolation between vias and pads, beyond what the resistivity of the substrate provides.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, while the disclosure describes an embodiment including a MEMS switch, it should be understood that this embodiment is exemplary only, and that the systems and methods disclosed here may be applied to any number of alternative MEMS or non-MEMS devices. Accordingly, the exemplary implementations set forth above, are intended to be illustrative, not limiting.

What is claimed is:

1. A method for forming a via, comprising:
forming at least one trench with a dead-end wall in a front side of a substrate;
forming a seed layer structure in the trench;
using reverse pulse plating to fill the trench with a conductive material; and
removing material from a back side of the substrate to a point at which the dead-end wall of the trench has been substantially removed.

2. The method of claim 1, wherein forming the seed layer structure comprises forming a seed layer structure including a layer of chromium and a layer of gold.

3. The method of claim 2, wherein using reverse pulse plating comprises
a) applying a forward current for a first duration;
b) applying a reverse current for a second duration;
c) applying no current for a third duration; and
d) repeating steps a) through c) for about 8 hours.

4. The method of claim 3, wherein the forward current is between about about 0.1 A to about 1 A, and the first duration is between about 10 msec to about 200 msec and wherein the reverse current is between about 1 A to about 10 A and the second duration is between about 1 msec to about 10 msec.

5. The method of claim 3, wherein the forward current is about 0.4 A and the first duration is about 100 msec, and the reverse current is about 4 A and the second duration is about 5 msec.

6. The method of claim 3, wherein the third duration is between about 1 msec and about 100 msec.

7. The method of claim 3, wherein the ratio of reverse current to forward current is about ten.

8. The method of claim 3, wherein the ratio of the first duration to the second duration is about twenty.

9. The method of claim 1, wherein the conductive material is at least one of copper, gold, and nickel.

10. The method of claim 1, wherein forming the seed layer structure comprises forming the seed layer structure using at least one of chemical vapor deposition, physical vapor deposition, ion beam deposition, e-beam deposition, evaporation and sputtering.

11. The method of claim 1, further comprising:
planarizing the front side of the substrate using chemical mechanical planarization; and
forming a conductive pad over the conductive material, of a thickness sufficient to provide a barrier to the transmission of gasses through the conductive pad.

12. The method of claim 1, wherein removing material from the back side of the substrate comprises removing material from the back side using at least one of grinding, lapping, polishing, single-sided wet etching, dry etching and any combination thereof.

13. A substrate for the formation of a device, comprising:
at least one opening formed through the substrate;
a seed layer structure including a layer of gold and a layer of chromium deposited in the opening; and
a conductive material deposited into the opening over the seed layer structure, providing an electrical connection to the device.

14. The substrate of claim 13, wherein a ratio of a depth of the opening to a width is at least one-to-one.

15. The substrate of claim 13, wherein the opening is between about 20 μm and about 50 μm wide, and between about 80 μm to about 150 μm deep.

16. The substrate of claim 13, wherein the conductive material comprises at least one of copper, gold and nickel.

17. The substrate of claim 13, wherein the gold layer of the seed layer structure is between about 3000 Angstroms and about 1 μm thick, and the chromium layer of the seed layer structure is between about 50 Angstroms and about 1500 Angstroms thick.

18. The substrate of claim 13, further comprising a conductive pad formed over the conductive material, of a thickness sufficient to provide a barrier to the transmission of gasses across the conductive pad.

19. The substrate of claim 18, wherein the conductive pad comprises gold in a thickness of between about 2500 Angstroms and about 1 μm.

20. A device, comprising at least one of a MEMS microstructure, a MEMS actuator, a MEMS sensor and an integrated circuit formed on the surface of the substrate of claim 13.

21. The device of claim 20, further comprising a lid hermetically sealed to the substrate, and covering the device.

22. An apparatus for forming a via, comprising:
means for forming at least one trench with a dead-end wall in a front side of a substrate;
means for forming a seed layer in the trench;
means for using reverse pulse plating to deposit a conductive material within the trench; and
means for removing material from a back side of the substrate to a point at which the dead-end wall of the trench has been substantially removed.
